(19) United States
(12) Patent Application Publication
(10) Pub. No.: US 2026/0282654 A1
(43) Pub. Date: Sep. 17, 2026

(54) Display Device And Electronic Device

(71) Applicant: Samsung Display Co., Ltd., Yongin-si (KR)

(72) Inventors: Jang Mi Kang, Yongin-si (KR); Jin Seon KWAK, Yongin-si, (KR); Kyung Bae KIM, Yongin-si (KR); Keon Min OH, Yongin-si, (KR); Yun Jang PYUN, Yongin-si (KR)

(73) Assignee: Samsung Display Co., Ltd., Yongin-si (KR)

(21) Appl. No.: 19/548,014

(22) Filed: Feb. 24, 2026

(30) Foreign Application Priority Data
Mar. 11, 2025 (KR) 10-2025-0031056

(51) Int. Cl. H10K 59/121; G09G 3/3266; H10D 86/40; H10D 86/60

(52) U.S. Cl. CPC H10K 59/1213; G09G 3/3266; H10D 86/423; H10D 86/60; G09G 2330/021

(57) ABSTRACT

The present disclosure relates to a display device and an electronic device in which an area of a display area may be expanded. The display device includes: a substrate having a display area and a non-display area; and a driving circuit layer, a pixel circuit layer, and a display element layer that are disposed on the substrate, wherein the driving circuit layer is connected to a pixel circuit of the pixel circuit layer, the pixel circuit of the pixel circuit layer is connected to a light emitting element of the display element layer, the driving circuit layer, the pixel circuit layer, and the display element layer are disposed on the display area of the substrate so as to overlap each other in a direction perpendicular to an extension direction of the substrate, the driving circuit layer includes a first transistor, the pixel circuit layer includes a second transistor provided in the pixel circuit and connected to the first transistor, the first transistor is a metal oxide semiconductor field effect transistor (MOSFET), and the second transistor is an oxide semiconductor transistor.

### CROSS-REFERENCE TO RELATED APPLICATION

This application claims priority from Korean Patent Application No. 10-2025-0031056 filed on Mar. 11, 2025 in the Korean Intellectual Property Office, and all the benefits accruing therefrom under 35 U.S.C. 119, the contents of which in its entirety are herein incorporated by reference.

### TECHNICAL FIELD

The present disclosure relates to a display device, and more particularly, to a display device and an electronic device in which an area of a display area may be expanded.

### BACKGROUND

An organic light emitting display apparatus includes display elements whose luminance is changed by a current, such as organic light emitting diodes.

### SUMMARY

Aspects of the present disclosure provide a display device and an electronic device in which an area of a display area may be expanded.

According to an aspect of the present disclosure, a display device includes: a substrate having a display area and a non-display area; and a driving circuit layer, a pixel circuit layer, and a display element layer that are disposed on the substrate, wherein the driving circuit layer is connected to a pixel circuit of the pixel circuit layer, the pixel circuit of the pixel circuit layer is connected to a light emitting element of the display element layer, the driving circuit layer, the pixel circuit layer, and the display element layer are disposed on the display area of the substrate so as to overlap each other in a direction perpendicular to an extension direction of the substrate, the driving circuit layer includes a first transistor, the pixel circuit layer includes a second transistor provided in the pixel circuit and connected to the first transistor, the first transistor is a metal oxide semiconductor field effect transistor (MOSFET), and the second transistor is an oxide semiconductor transistor.

According to another aspect of the present disclosure, a display device includes: a substrate having a display area and a non-display area; and a driving circuit layer, a pixel circuit layer, and a display element layer that are disposed on the substrate, wherein the driving circuit layer is connected to a pixel circuit of the pixel circuit layer, the pixel circuit of the pixel circuit layer is connected to a light emitting element of the display element layer, the driving circuit layer, the pixel circuit layer, and the display element layer are disposed on the display area of the substrate so as to overlap each other in a direction perpendicular to an extension direction of the substrate, the driving circuit layer includes a first transistor, the pixel circuit layer includes a second transistor provided in the pixel circuit and connected to the first transistor, and each of the first transistor and the second transistor is an oxide semiconductor transistor.

According to still another aspect of the present disclosure, an electronic device includes a display device providing a display screen, wherein the display device includes: a substrate having a display area and a non-display area; and a driving circuit layer, a pixel circuit layer, and a display element layer that are disposed on the substrate, the driving circuit layer is connected to a pixel circuit of the pixel circuit layer, the pixel circuit of the pixel circuit layer is connected to a light emitting element of the display element layer, the driving circuit layer, the pixel circuit layer, and the display element layer are disposed on the display area of the substrate so as to overlap each other in a direction perpendicular to an extension direction of the substrate, the driving circuit layer includes a first transistor, the pixel circuit layer includes a second transistor provided in the pixel circuit and connected to the first transistor, the first transistor is a MOSFET, and the second transistor is an oxide semiconductor transistor.

According to an aspect, an area of a display area may be expanded.

For example, since driving circuits and pixels are formed in a vertical stack form in the display area, an area of a non-display area may be reduced, whereas an area of the display area may be expanded.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail aspects thereof with reference to the attached drawings, in which:

FIG. 1 is an exploded perspective view illustrating a display device according to an aspect;

FIG. 2 is a block diagram illustrating the display device according to an aspect;

FIG. 3 is a layout diagram illustrating an example of a display panel according to an aspect;

FIGS. 4 and 5 are layout diagrams illustrating aspects of a display area of FIG. 3;

FIG. 6 is a cross-sectional view illustrating the display panel of the display device according to an aspect;

FIG. 7 is a layout diagram illustrating an example of a display panel according to another aspect;

FIG. 8 is a cross-sectional view illustrating the display panel of the display device according to another aspect;

FIG. 9 is a view for describing connections between scan drivers and scan lines according to an aspect;

FIG. 10 is a layout diagram illustrating an example of a display panel according to still another aspect;

FIG. 11 is a block diagram of an electronic device according to an aspect; and

FIGS. 12 to 14 are schematic views of electronic devices according to various aspects.

### DETAILED DESCRIPTION

The present disclosure will now be described more fully hereinafter with reference to the accompanying drawings, in which preferred aspects of the present disclosure are shown. Aspects of the present disclosure may, however, be embodied in different forms and should not be construed as limited to the aspects set forth herein.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more aspects. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various aspects of the present disclosure may be combined partially or totally. As will be clearly appreciated by those skilled in the art, technically various interactions and operations are possible. Various aspects can be practiced individually or in combination.

Hereinafter, specific exemplary aspects will be described with reference to the accompanying drawings.

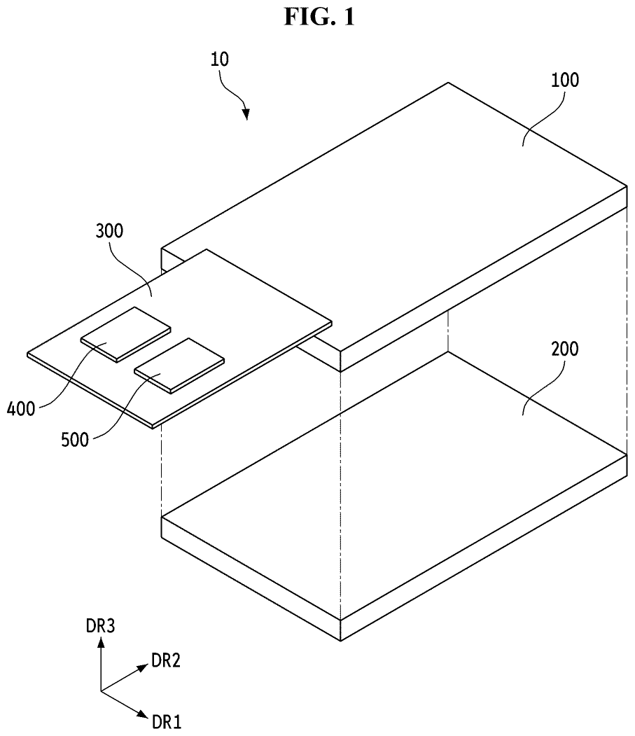

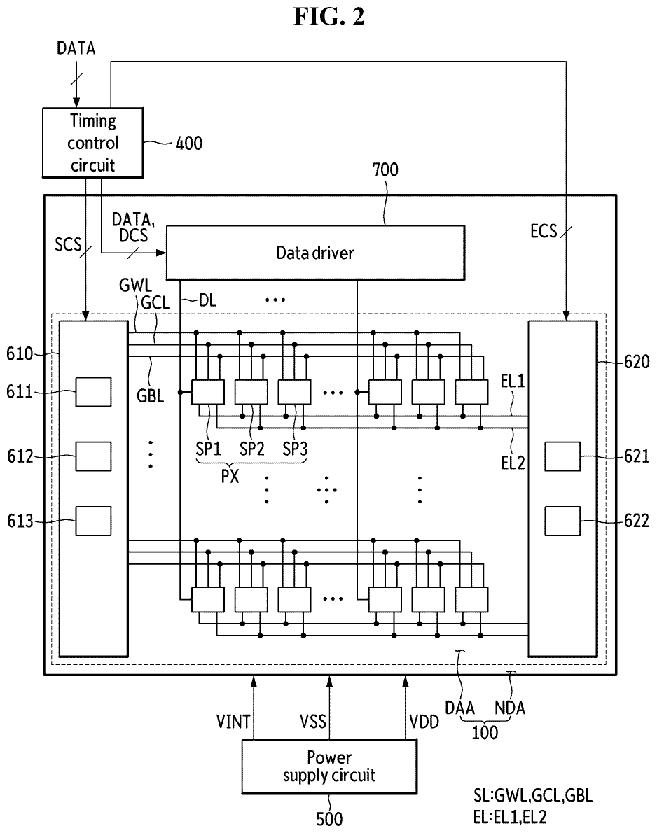

FIG. 1 is an exploded perspective view illustrating a display device according to an aspect. FIG. 2 is a block diagram illustrating the display device according to an aspect.

Referring to FIGS. 1 and 2, a display device 10 according to an aspect is a device that displays a moving image or a still image. The display device 10 according to an aspect may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according an aspect may be applied as a display unit of televisions, laptop computers, monitors, billboards, or the Internet of Things (IOTs). Alternatively, the display device 10 according an aspect may be applied to smart watches, watch phones, or head mounted displays (HMDs) for implementing virtual reality and augmented reality.

The display device 10 according to an aspect includes a display panel 100, a heat dissipation layer 200, a circuit board 300, a timing control circuit 400, and a power supply circuit 500.

The display panel 100 may have a shape similar to a rectangular shape in plan view. For example, the display panel 100 may have a shape similar to a rectangular shape, in plan view, having short sides in a first direction DR1 and long sides in a second direction DR2 crossing the first direction DR1. In the display panel 100, a corner where the short side in the first direction DR1 and the long side in the second direction DR2 meet may be rounded with a selected curvature or right-angled. A shape of the display panel 100 in plan view is not limited to the rectangular shape, and may be a shape similar to other polygonal shapes, a circular shape, or an elliptical shape. A shape of the display device 10 in plan view may follow the shape of the display panel 100 in plan view, but an aspect of the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA that displays an image and a non-display area NDA that does not display an image, as illustrated in FIG. 2.

The plurality of pixels PX may be disposed in the display area DAA. The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

Each of the plurality of pixels PX includes a plurality of sub-pixels SP1, SP2, and SP3. The plurality of sub-pixels SP1, SP2, and SP3 may include transistors.

Each of the plurality of sub-pixels SP1, SP2, and SP3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of sub-pixels SP1, SP2, and SP3 may receive a data voltage of the data line DL according to a write scan signal of the write scan line GWL, and allow a light emitting element to emit light according to the data voltage.

The scan driver 610 and the emission driver 620 may be disposed in the display area DAA. The plurality of pixels, the scan driver 610 and the emission driver 620 may overlap in a third direction DR3 in the display area DAA.

The scan driver 610 may include a plurality of scan transistors, and the emission driver 620 may include a plurality of emission transistors.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may be disposed in the non-display area NDA. The data driver 700 may include a plurality of data transistors. The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

Referring to FIG. 1, the heat dissipation layer 200 may overlap the display panel 100 in the third direction DR3, which is a thickness direction of the display panel 100. The heat dissipation layer 200 may be disposed on one surface, for example, a rear surface, of the display panel 100. The heat dissipation layer 200 serves to dissipate heat generated from the display panel 100. The heat dissipation layer 200 may include a layer made of graphite or metal such as silver (Ag), copper (Cu), or aluminum (Al) having high thermal conductivity.

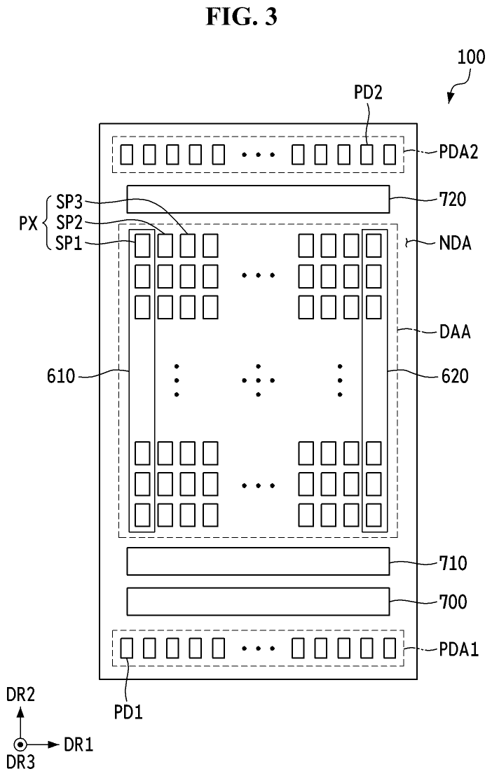

The circuit board 300 may be electrically connected to a plurality of first pads PD1 (see FIG. 3) of a first pad unit PDA1 (see FIG. 3) of the display panel 100 using a conductive adhesive member such as an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. The other end of the circuit board 300 may be connected to the plurality of first pads PD1 (see FIG. 3) of the first pad unit PDA1 (see FIG. 3) of the display panel 100 using the conductive adhesive member. One end of the circuit board 300 may be an end opposite to the other end of the circuit board 300.

Referring to FIG. 2, the timing control circuit 400 may receive digital video data and timing signals from the outside. The timing control circuit 400 may generate the scan timing control signal SCS, the emission timing control signal ECS, and the data timing control signal DCS for controlling the display panel 100 according to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

The power supply circuit 500 may generate a plurality of panel driving voltages according to an external source voltage. For example, the power supply circuit 500 may generate a first driving voltage VSS, a second driving voltage VDD, and a third driving voltage VINT and supply the first driving voltage VSS, the second driving voltage VDD, and the third driving voltage VINT to the display panel 100.

Referring to FIG. 1, each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similar to the data driver 700. In this case, the timing control circuit 400 may include a plurality of timing transistors, and the power supply circuit 500 may include a plurality of power transistors. Each of the timing control circuit 400 and the power supply circuit 500 may be disposed between the data driver 700 and the first pad unit PDA1 (see FIG. 3).

FIG. 3 is a layout diagram illustrating an example of a display panel according to an aspect.

Referring to FIG. 3, a plurality of pixels PX, a scan driver 610, and an emission driver 620 may be disposed in the display area DAA of the display panel 100 according to an aspect. The plurality of pixels PX may be disposed in a matrix form in the display area DAA. For example, a plurality of sub-pixels SP1, SP2, and SP3 may be disposed in a matrix form in the display area DAA.

The scan driver 610 and the emission driver 620 may overlap the pixel PX (or the sub-pixels SP1, SP2, and SP3). For example, the scan driver 610 and the emission driver 620 may overlap the pixel PX (or the sub-pixels SP1, SP2, and SP3) in the display area DAA. Here, when an area of the display area DAA that overlaps the scan driver 610 and the emission driver 620 is defined as an overlapping area and an area of the display area DAA that does not overlap the scan driver 610 and the emission driver 620 is defined as a non-overlapping area, an area of the overlapping area may be smaller than an area of the non-overlapping area.

A data driver 700, a first distribution circuit 710, a second distribution circuit 720, a first pad unit PDA1, and a second pad unit PDA2 may be disposed in the non-display area NDA of the display panel 100.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on one side of the display area DAA in the second direction DR2. The first pad unit PDA1 may be disposed outside the data driver 700 in the second direction DR2. For example, the first pad unit PDA1 may be closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The second pad unit PDA2 may be disposed on a fourth side of the display area DAA. For example, the second pad unit PDA2 may be disposed on the other side of the display area DAA in the second direction DR2. The second pad unit PDA2 may be disposed outside the second distribution circuit 720 in the second direction DR2. That is, the second pad unit PDA2 may be closer to an edge of the display panel 100 than the second distribution circuit 720 is.

The first distribution circuit 710 distributes data voltages applied through the first pad unit PDA1 to the plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA. The first distribution circuit 710 may include a plurality of first distribution transistors. The first distribution circuit 710 may be connected to the data driver 700 and the data lines DL. For example, the first distribution circuit 710 may provide the data voltage from the data driver 700 to the data lines DL.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA. The second distribution circuit 720 may include a plurality of second distribution transistors.

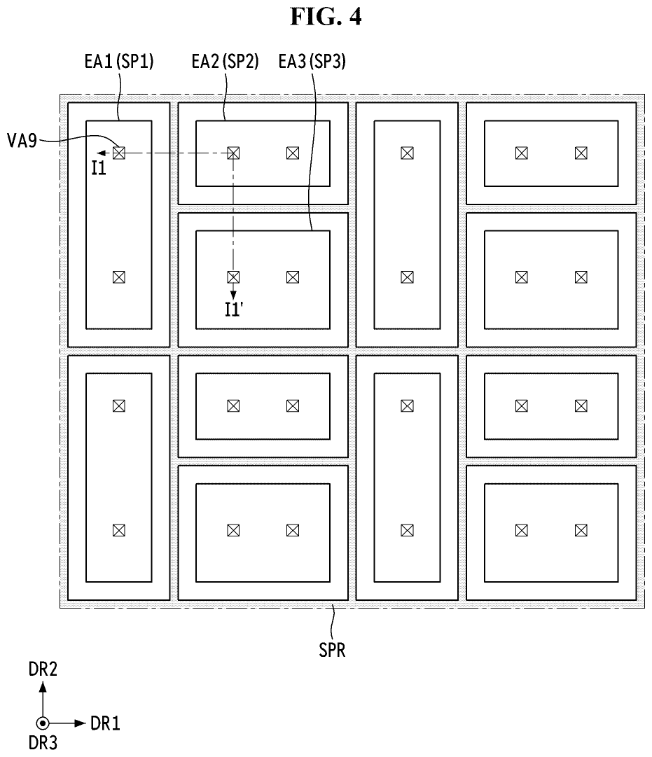

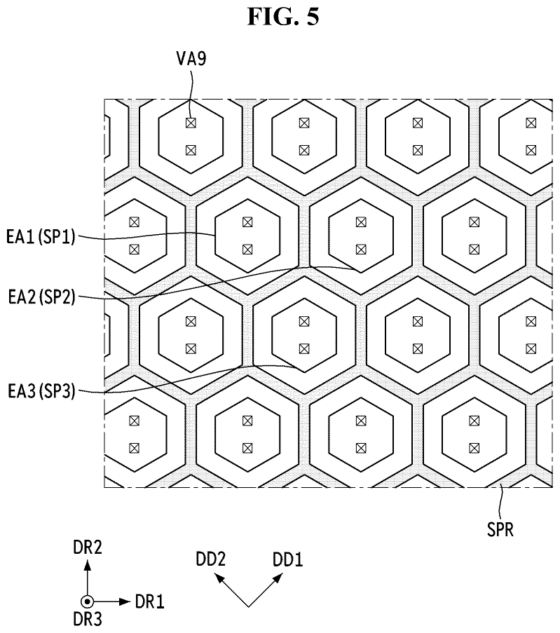

FIGS. 4 and 5 are layout diagrams illustrating aspects of a display area of FIG. 3.

Referring to FIGS. 4 and 5, each of the plurality of pixels PX may include a first emission area EA1 that is an emission area of a first sub-pixel SP1, a second emission area EA2 that is an emission area of a second sub-pixel SP2, and a third emission area EA3 that is an emission area of a third sub-pixel SP3.

Each of the first emission area EA1, the second emission area EA2, and the third emission area EA3 may have a polygonal shape, a circular shape, an elliptical shape, or an irregular shape in plan view.

A maximum length of the first emission area EA1 in the first direction DR1 may be smaller than a maximum length of the second emission area EA2 in the first direction DR1 and a maximum length of the third emission area EA3 in the first direction DR1. The maximum length of the second emission area EA2 in the first direction DR1 and the maximum length of the third emission area EA3 in the first direction DR1 may be substantially the same as each other.

A maximum length of the first emission area EA1 in the second direction DR2 may be greater than a maximum length of the second emission area EA2 in the second direction DR2 and a maximum length of the third emission area EA3 in the second direction DR2. The maximum length of the second emission area EA2 in the second direction DR2 may be smaller than the maximum length of the third emission area EA3 in the second direction DR2. The maximum length of the first emission area EA1 in the second direction DR2 may be greater than the maximum length of the second emission area EA2 in the second direction DR2.

Each of the first emission area EA1, the second emission area EA2, and the third emission area EA3 may have a hexagonal shape including six straight lines, in plan view, as illustrated in FIG. 5, but an aspect of the present disclosure is not limited thereto. Each of the first emission area EA1, the second emission area EA2, and the third emission area EA3 may have polygonal shapes other than the hexagonal shape, a circular shape, an elliptical shape, or an irregular shape in plan view.

As illustrated in FIG. 4, in each of the plurality of pixels PX, the first emission area EA1 and the second emission area EA2 may neighbor to each other in the first direction DR1. In addition, the first emission area EA1 and the third emission area EA3 may neighbor to each other in the first direction DR1. In addition, the second emission area EA3 and the third emission area EA3 may neighbor to each other in the second direction DR2. An area of the first emission area EA1, an area of the second emission area EA2, and an area of the third emission area EA3 may be different from each other.

Alternatively, as illustrated in FIG. 5, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

The first sub-pixel SP1 may emit first light that has passed through a first color filter among light emitted from the first emission area EA1, the second sub-pixel SP2 may emit second light that has passed through a second color filter among light emitted from the second emission area EA2, and the third sub-pixel SP3 may emit third light that has passed through a third color filter among light emitted from the third emission area EA3.

The first light, the second light, and the third light described above may be light of different wavelength bands. For example, one of the first light, the second light, and the third light may be light of a blue wavelength band, another of the first light, the second light, and the third light may be light of a green wavelength band, and the other of the first light, the second light, and the third light may be light of a red wavelength band. Here, the light of the blue wavelength band may indicate that a main peak wavelength of the light is included in a wavelength band of approximately 370 nm to 460 nm, the light of the green wavelength band may indicate that a main peak wavelength of the light is included in a wavelength band of approximately 480 nm to 560 nm, and the light of the red wavelength band may indicate that a main peak wavelength of the light is included in a wavelength band of approximately 600 nm to 750 nm.

It has been illustrated in FIGS. 4 and 5 that each of the plurality of sub-pixels SP1, SP2, and SP2 includes three emission areas EA1, EA2, and EA3, but an aspect of the present disclosure is not limited thereto.

In addition, an arrangement of the emission areas of the plurality of pixels PX is not limited to those illustrated in FIGS. 4 and 5. For example, the emission areas of the plurality of pixels PX may be disposed in a stripe structure in which the emission areas are arranged in the first direction DR1, a PenTile® structure in which the emission areas have a diamond arrangement, or a hexagonal structure in which the emission areas having a hexagonal shape in plan view are arranged as illustrated in FIG. 5.

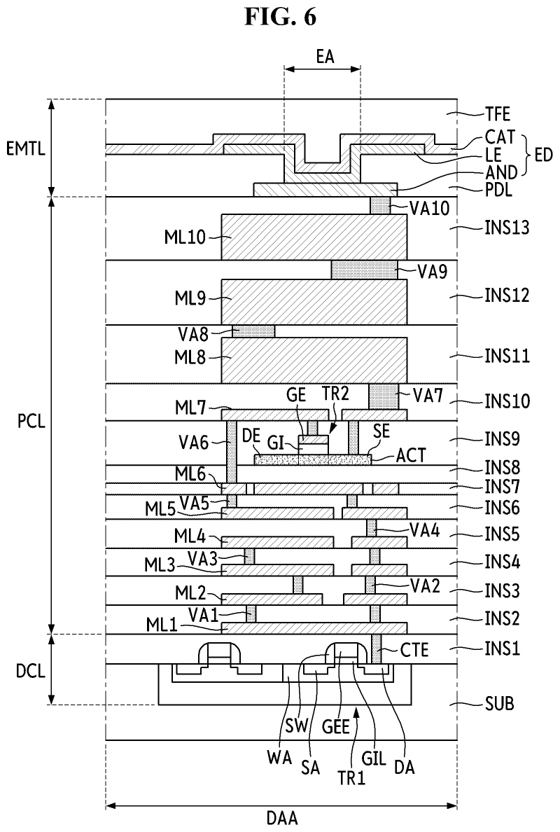

FIG. 6 is a cross-sectional view illustrating the display panel 100 of the display device 10 according to an aspect. For example, FIG. 6 may be a cross-sectional view of the display panel 100 of FIG. 3.

The display panel 100 according to an aspect may include a substrate SUB (e.g., a semiconductor substrate SUB), a driving circuit layer DCL, a pixel circuit layer PCL, and a display element layer EMTL, as illustrated in FIG. 6.

The driving circuit layer DCL, the pixel circuit layer PCL, and the display element layer EMTL may be disposed on the display area DAA of the semiconductor substrate SUB so as to overlap each other in a direction perpendicular to an extension direction (e.g., the first direction DR1 and the second direction DR2) of the semiconductor substrate SUB. In other words, the driving circuit layer DCL, the pixel circuit layer PCL, and the display element layer EMTL may be disposed on the display area DAA of the semiconductor substrate SUB so as to overlap each other in a direction perpendicular to the upper surface of the semiconductor substrate SUB.

The driving circuit layer DCL may be disposed between the semiconductor substrate SUB and the pixel circuit layer PCL.

The pixel circuit layer PCL may be disposed between the driving circuit layer DCL and the display element layer EMTL.

The semiconductor substrate SUB may be a wafer substrate. The semiconductor substrate SUB may be a substrate doped with first-type impurities.

The driving circuit layer DCL may be disposed on the display area DAA of the semiconductor substrate SUB. The driving circuit layer DCL may include the scan driver 610 and the emission driver 620.

The driving circuit layer DCL may include a plurality of first transistors TR1. The first transistor TR1 may be, for example, a metal oxide semiconductor field effect transistor (MOSFET). In this case, each of the plurality of first transistors TR1 may have the form of a complementary metal oxide semiconductor (CMOS). The first transistor TR1 may be, for example, at least one of the scan transistor of the scan driver 610 and the emission transistor of the emission driver 620 described above. In other words, the scan driver 610 may include the plurality of first transistors TR1, and the emission driver 620 may include the plurality of first transistors TR1.

A well region WA may be disposed in an upper surface of the semiconductor substrate SUB in the display area DAA. The well region WA may be a region doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

The well region WA may include a source region SA corresponding to a source electrode of the first transistor TR1 and a drain region DA corresponding to a drain electrode of the first transistor TR1.

A gate insulating layer GIL may be disposed between a gate electrode GEE and the well region WA. Side surface insulating layers SW may be disposed on side surfaces of the gate electrode GEE.

The first transistor TR1 may include the gate electrode GEE, the source region SA, and the drain region DA.

The pixel circuit layer PCL may be disposed on the driving circuit layer DCL. For example, the pixel circuit layer PCL may be disposed on the driving circuit layer DCL in the display area DAA of the semiconductor substrate SUB. The pixel circuit layer PCL may include a plurality of second transistors TR2. Here, the second transistor TR2 may be the pixel transistor described above. The plurality of sub-pixels may include the plurality of second transistors TR2, respectively, and the plurality of second transistors TR2 may be disposed in the pixel circuit layer PCL. The second transistors TR2 of the pixel circuit layer PCL may be connected to the first transistors TR1 (e.g., the scan transistor and the emission transistor) of the driving circuit layer DCL.

The second transistor TR2 may include a gate electrode GE, a source electrode SE of an active layer ACT, and a drain electrode DE of the active layer ACT. The second transistor TR2 described above may be an oxide-based transistor (e.g., an oxide semiconductor transistor). For example, the second transistor TR2 may be an N-type oxide-based transistor. In other words, the second transistor TR2 may include an oxide semiconductor (or an oxide semiconductor material). The oxide semiconductor has high carrier mobility and a low leakage current, and thus, a voltage drop is not great even though a driving time is long. For example, in a case of the oxide semiconductor, even at the time of driving at a low frequency, a color change of an image according to a voltage drop is not great, and thus, driving at a low frequency is possible. Accordingly, by making the second transistor TR2 include the oxide semiconductor material, it is possible to implement a display device in which the occurrence of a leakage current is prevented and power consumption is reduced.

The display element layer EMTL may be disposed on the pixel circuit layer PCL. For example, the display element layer EMTL may be disposed on the pixel circuit layer PCL in the display area DAA of the semiconductor substrate SUB. The plurality of sub-pixels SP1, SP2, and SP3 may include a plurality of light emitting elements ED, respectively, and the plurality of light emitting elements ED may be disposed in the display element layer EMTL. One sub-pixel (e.g., SP1) may include a pixel circuit of the pixel circuit layer PCL and a light emitting element ED connected to the pixel circuit. The light emitting element ED may include a first electrode AND (e.g., an anode electrode), a light emitting layer LE (e.g., an organic light emitting layer), and a second electrode CAT (e.g., a cathode electrode).

A first insulating layer INS1 may be disposed on the semiconductor substrate SUB.

A first conductive layer ML1 may be disposed on the first insulating layer INS1. The first conductive layer ML1 may be connected to the drain region DA of the first transistor TR1 through an intermediate connection electrode CTE penetrating through the first insulating layer INS1.

A second insulating layer INS2 may be disposed on the first conductive layer ML1.

A second conductive layer ML2 may be disposed on the second insulating layer INS2. The second conductive layer ML2 may be connected to the first conductive layer ML1 through a first via electrode VA1 penetrating through the second insulating layer INS2.

A third insulating layer INS3 may be disposed on the second conductive layer ML2.

A third conductive layer ML3 may be disposed on the third insulating layer INS3. The third conductive layer ML3 may be connected to the second conductive layer ML2 through a second via electrode VA2 penetrating through the third insulating layer INS3.

A fourth insulating layer INS4 may be disposed on the third conductive layer ML3.

A fourth conductive layer ML4 may be disposed on the fourth insulating layer INS4. The fourth conductive layer ML4 may be connected to the third conductive layer ML3 through a third via electrode VA3 penetrating through the fourth insulating layer INS4.

A fifth insulating layer INS5 may be disposed on the fourth conductive layer ML4.

A fifth conductive layer ML5 may be disposed on the fifth insulating layer INS5. The fifth conductive layer ML5 may be connected to the fourth conductive layer ML4 through a fourth via electrode VA4 penetrating through the fifth insulating layer INS5.

A sixth insulating layer INS6 may be disposed on the fifth conductive layer ML5.

A sixth conductive layer ML6 may be disposed on the sixth insulating layer INS6. The sixth conductive layer ML6 may be connected to the fifth conductive layer ML5 through a fifth via electrode VA5 penetrating through the sixth insulating layer INS6.

A seventh insulating layer INS7 may be disposed on the sixth conductive layer ML6.

An eighth insulating layer INS8 may be disposed on the seventh insulating layer INS7.

The active layer ACT may be disposed on the eighth insulating layer INS8. The active layer ACT may include the drain electrode DE and the source electrode SE. The active layer ACT may include oxide. For example, the active layer ACT may be a semiconductor layer including indium gallium zinc oxide (IGZO) or indium gallium zinc tin oxide (IGZTO). However, the present disclosure is not limited thereto, and the active layer may also include amorphous silicon.

A gate insulating layer GI may be disposed on the active layer ACT.

The gate electrode GE may be disposed on the gate insulating layer GI.

A ninth insulating layer INS9 may be disposed on the gate electrode GE, the gate insulating layer GI, the active layer ACT, and the eighth insulating layer INS8.

A seventh conductive layer ML7 may be disposed on the ninth insulating layer INS9. The seventh conductive layer ML7 may be connected to the sixth conductive layer ML6, the gate electrode GE of the second transistor TR2, and the source electrode SE of the second transistor TR2. For example, one seventh conductive layer ML7 may be connected to the sixth conductive layer ML6 through a sixth via electrode VA6 penetrating through the ninth insulating layer INS9 and the eighth insulating layer INS8, another seventh conductive layer ML7 may be connected to the gate electrode GE through a sixth via electrode VA6 penetrating through the ninth insulating layer INS9, and still another seventh conductive layer ML7 may be connected to the source electrode SE through a sixth via electrode VA6 penetrating through the ninth insulating layer INS9.

A tenth insulating layer INS10 may be disposed on the seventh conductive layer ML7.

An eighth conductive layer ML8 may be disposed on the tenth insulating layer INS10. The eighth conductive layer ML8 may be connected to the seventh conductive layer ML7 through a seventh via electrode VA7 penetrating through the tenth insulating layer INS10.

An eleventh insulating layer INS11 may be disposed on the eighth conductive layer ML8.

A ninth conductive layer ML9 may be disposed on the eleventh insulating layer INS11. The ninth conductive layer ML9 may be connected to the eighth conductive layer ML8 through an eighth via electrode VA8 penetrating through the eleventh insulating layer INS11.

A twelfth insulating layer INS12 may be disposed on the ninth conductive layer ML9.

A tenth conductive layer ML10 may be disposed on the twelfth insulating layer INS12. The tenth conductive layer ML10 may be connected to the ninth conductive layer ML9 through a ninth via electrode VA9 penetrating through the twelfth insulating layer INS12.

A thirteenth insulating layer INS13 may be disposed on the tenth conductive layer ML10.

The first electrode AND may be disposed on the thirteenth insulating layer INS13. The first electrode AND may be connected to the tenth conductive layer ML10 through a tenth via electrode VA10 penetrating through the thirteenth insulating layer INS13.

A pixel defining layer PDL may be disposed on the first electrode AND. The pixel defining layer PDL may be disposed on an edge of the first electrode AND so as to overlap the edge of the first electrode AND. The pixel defining layer PDL may define an emission area EA of the sub-pixel. The first electrode AND may be exposed to the outside of the pixel defining layer PDL by the emission area EA of the pixel defining layer PDL.

The light emitting layer LE may be disposed on the first electrode AND and the pixel defining layer PDL.

The second electrode CAT may be disposed on the light emitting layer LE and the pixel defining layer PDL.

An encapsulation layer TFE may be disposed on the second electrode CAT. The encapsulation layer TFE may be formed as a composite film including an inorganic layer, an organic layer, and an inorganic layer. The encapsulation layer TFE may prevent moisture from permeating through into the light emitting layer LE. A color filter may be disposed on the encapsulation layer TFE.

The drain region DA of the first transistor TR1 may be connected to the gate electrode GE of the second transistor TR2 through the intermediate connection electrode CTE, the first to seventh conductive layers ML1 to ML7, and the first to sixth via electrodes VA1 to VA6. Accordingly, a scan signal (or an emission control signal) output through the first transistor TR1 may be applied to the gate electrode GE of the second transistor TR2. For example, a write scan signal output through the scan transistor may be applied to the gate electrode GE of the second transistor TR2. Here, the seventh conductive layer ML7 connected to the gate electrode GE of the second transistor TR2 may be a scan line (e.g., a write scan line GWL).

A signal (e.g., a data voltage) output through the second transistor TR2 may be applied to the first electrode AND through the seventh to tenth conductive layers ML7 to ML10 and the seventh to tenth via electrodes VA7 to VA10.

According to an aspect, the driving circuit layer DCL, the pixel circuit layer PCL, and the display element layer EMTL are disposed in the display area DAA so as to overlap each other, and thus, an area of the non-display area NDA may be reduced. In addition, the driving circuit layer DCL is disposed in the display area DAA rather than the non-display area NDA, and thus, a margin area of the non-display area NDA may be increased, and the display area DAA may be expanded to the margin area.

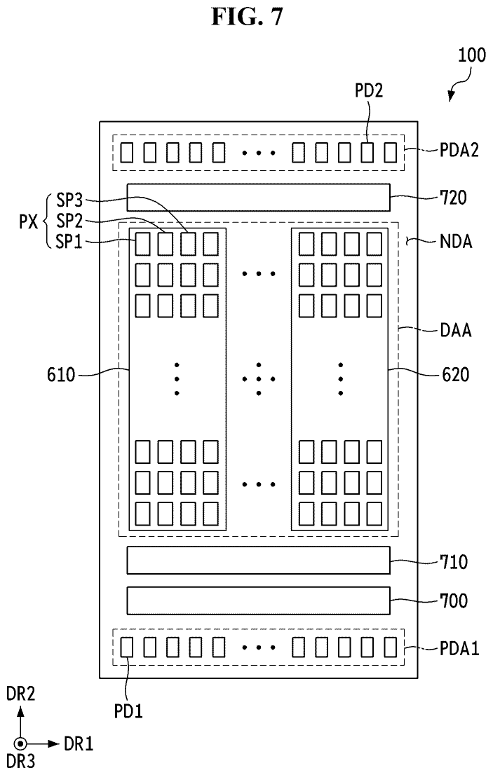

FIG. 7 is a layout diagram illustrating an example of a display panel 100 according to another aspect.

The display panel 100 of FIG. 7 is different from the display panel 100 described above with reference to FIG. 3 in a size of an overlapping area of the display area DAA, and such a difference will be mainly described below.

As illustrated in FIG. 7, the plurality of pixels PX (or the plurality of sub-pixels SP1, SP2, and SP3), the scan driver 610, and the emission driver 620 may be disposed in the display area DAA. Here, when an area of the display area DAA that overlaps the scan driver 610 and the emission driver 620 is defined as an overlapping area and an area of the display area DAA that does not overlap the scan driver 610 and the emission driver 620 is defined as a non-overlapping area, an area of the overlapping area may be greater than an area of the non-overlapping area.

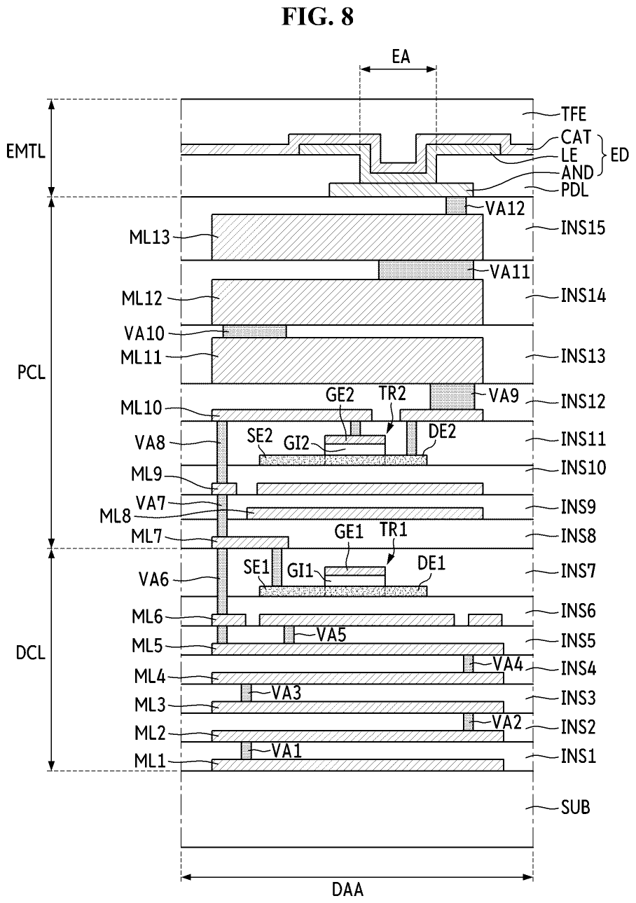

FIG. 8 is a cross-sectional view illustrating the display panel 100 of the display device 10 according to another aspect. For example, FIG. 8 may be a cross-sectional view of the display panel 100 of FIG. 7.

The display panel 100 according to another aspect may include a substrate SUB (e.g., a semiconductor substrate SUB), a driving circuit layer DCL, a pixel circuit layer PCL, and a display element layer EMTL, as illustrated in FIG. 8.

The driving circuit layer DCL, the pixel circuit layer PCL, and the display element layer EMTL may be disposed on the display area DAA of the semiconductor substrate SUB so as to overlap each other in a direction perpendicular to an extension direction (e.g., the first direction DR1 and the second direction DR2) of the semiconductor substrate SUB. In the words, the driving circuit layer DCL, the pixel circuit layer PCL, and the display element layer EMTL may be disposed on the display area DAA of the semiconductor substrate SUB so as to overlap each other in a direction perpendicular to the upper surface of the semiconductor substrate SUB.

The driving circuit layer DCL may be disposed between the semiconductor substrate SUB and the pixel circuit layer PCL.

The pixel circuit layer PCL may be disposed between the driving circuit layer DCL and the display element layer EMTL.

The semiconductor substrate SUB may be a wafer substrate. The semiconductor substrate SUB may be a substrate doped with first-type impurities.

The driving circuit layer DCL may be disposed on the display area DAA of the semiconductor substrate SUB. The driving circuit layer DCL may include the scan driver 610 and the emission driver 620.

The driving circuit layer DCL may include a plurality of first transistors TR1. The first transistor TR1 may include a first gate electrode GE1, a first source electrode SE1 of a first active layer ACT1, and a first drain electrode DE1 of the first active layer ACT1. The first transistor TR1 described above may be an oxide-based transistor (e.g., an oxide semiconductor transistor). For example, the first transistor TR1 may be an N-type oxide-based transistor. In other words, the first transistor TR1 may include an oxide semiconductor (or an oxide semiconductor material). The first transistor TR1 may be, for example, at least one of the scan transistor of the scan driver 610 and the emission transistor of the emission driver 620 described above. In other words, the scan driver 610 may include the plurality of first transistors TR1, and the emission driver 620 may include the plurality of first transistors TR1.

The pixel circuit layer PCL may be disposed on the driving circuit layer DCL. For example, the pixel circuit layer PCL may be disposed on the driving circuit layer DCL in the display area DAA of the semiconductor substrate SUB. The pixel circuit layer PCL may include a plurality of second transistors TR2. Here, the second transistor TR2 may be the pixel transistor described above. The plurality of sub-pixels SP1, SP2, and SP3 may include the plurality of second transistors TR2, respectively, and the plurality of second transistors TR2 may be disposed in the pixel circuit layer PCL. Pixel circuits may be connected to the first transistors TR1 (e.g., the scan transistor and the emission transistor) of the driver circuit layer DCL.

The second transistor TR2 may include a second gate electrode GE2, a second source electrode SE2 of a second active layer ACT2, and a second drain electrode DE2 of the second active layer ACT2. The second transistor TR2 described above may be an oxide-based transistor (e.g., an oxide semiconductor transistor). For example, the second transistor TR2 may be an N-type oxide-based transistor. In other words, the second transistor TR2 may include an oxide semiconductor (or an oxide semiconductor material).

The display element layer EMTL may be disposed on the pixel circuit layer PCL. For example, the display element layer EMTL may be disposed on the pixel circuit layer PCL in the display area DAA of the semiconductor substrate SUB. The plurality of sub-pixels SP1, SP2, and SP3 may include a plurality of light emitting elements ED, respectively, and the plurality of light emitting elements ED may be disposed in the display element layer EMTL. One sub-pixel (e.g., SP1) may include a pixel circuit of the pixel circuit layer PCL and a light emitting element ED connected to the pixel circuit. The light emitting element ED may include a first electrode AND (e.g., an anode electrode), a light emitting layer LE (e.g., an organic light emitting layer), and a second electrode CAT (e.g., a cathode electrode).

A first conductive layer ML1 may be disposed on a semiconductor substrate SUB.

A first insulating layer INS1 may be disposed on the first conductive layer ML1.

A second conductive layer ML2 may be disposed on the first insulating layer INS1. The second conductive layer ML2 may be connected to the first conductive layer ML1 through a first via electrode VA1 penetrating through the first insulating layer INS1.

A second insulating layer INS2 may be disposed on the second conductive layer ML2.

A third conductive layer ML3 may be disposed on the second insulating layer INS2. The third conductive layer ML3 may be connected to the second conductive layer ML2 via a second via electrode VA2 penetrating through the second insulating layer INS2.

A third insulating layer INS3 may be disposed on the third conductive layer ML3.

A fourth conductive layer ML4 may be disposed on the third insulating layer INS3. The fourth conductive layer ML4 may be connected to the third conductive layer ML3 via a third via electrode VA3 penetrating through the third insulating layer INS3.

A fourth insulating layer INS4 may be disposed on the fourth conductive layer ML4.

A fifth conductive layer ML5 may be disposed on the fourth insulating layer INS4. The fifth conductive layer ML5 may be connected to the fourth conductive layer ML4 via a fourth via electrode VA4 penetrating through the fourth insulating layer INS4.

A fifth insulating layer INS5 may be disposed on the fifth conductive layer ML5.

A sixth conductive layer ML6 may be disposed on the fifth insulating layer INS5. The sixth conductive layer ML6 may be connected to the fifth conductive layer ML5 through a fifth via electrode VA5 penetrating through the fifth insulating layer INS5.

A sixth insulating layer INS6 may be disposed on the sixth conductive layer ML6.

The first active layer ACT1 may be disposed on the sixth insulating layer INS6. The first active layer ACT1 may include the first drain electrode DE1 and the first source electrode SE1. The first active layer ACT1 may include oxide. For example, the first active layer ACT1 may be a semiconductor layer including indium gallium zinc oxide (IGZO) or indium gallium zinc tin oxide (IGZTO). However, the present disclosure is not limited thereto, and the first active layer ACT1 may also include amorphous silicon.

A first gate insulating layer GI1 may be disposed on the first active layer ACT1.

The first gate electrode GE1 may be disposed on the first gate insulating layer GI1.

A seventh insulating layer INS7 may be disposed on the first gate electrode GE1, the first gate insulating layer GI1, the first active layer ACT1, and the sixth insulating layer INS6.

A seventh conductive layer ML7 may be disposed on the seventh insulating layer INS7. The seventh conductive layer ML7 may be connected to the sixth conductive layer ML6 and the first source electrode SE1 of the first transistor TR1. For example, one seventh conductive layer ML7 may be connected to the sixth conductive layer ML6 through a sixth via electrode VA6 penetrating through the seventh insulating layer INS7 and the sixth insulating layer INS6, and another seventh conductive layer ML7 may be connected to the first source electrode SE1 through a sixth via electrode VA6 penetrating through the seventh insulating layer INS7.

An eighth insulating layer INS8 may be disposed on the seventh conductive layer ML7.

An eighth conductive layer ML8 may be disposed on the eighth insulating layer INS8. The eighth conductive layer ML8 may be disposed between the first transistor TR1 and the second transistor TR2. For example, the eighth conductive layer ML8 may be a light blocking layer disposed between the first transistor TR1 and the second transistor TR2.

A ninth insulating layer INS9 may be disposed on the eighth conductive layer ML8.

A ninth conductive layer ML9 may be disposed on the ninth insulating layer INS9. The ninth conductive layer ML9 may be connected to the seventh conductive layer ML7 through a seventh via electrode VA7 penetrating through the ninth insulating layer INS9 and the eighth insulating layer INS8. The ninth conductive layer ML9 disposed between the first transistor TR1 and the second transistor TR2 among the ninth conductive layers ML9 may be a light blocking layer.

A tenth insulating layer INS10 may be disposed on the ninth conductive layer ML9.

The second active layer ACT2 may be disposed on the tenth insulating layer INS10. The second active layer ACT2 may include the second drain electrode DE2 and the second source electrode SE2. The second active layer ACT2 may include oxide. For example, the second active layer ACT2 may be a semiconductor layer including indium gallium zinc oxide (IGZO) or indium gallium zinc tin oxide (IGZTO). However, the present disclosure is not limited thereto, and the second active layer ACT2 may also include amorphous silicon.

A second gate insulating layer GI2 may be disposed on the second active layer ACT2.

The second gate electrode GE2 may be disposed on the second gate insulating layer GI2.

An eleventh insulating layer INS11 may be disposed on the second gate electrode GE2, the second gate insulating layer GI2, the second active layer ACT2, and the tenth insulating layer INS10.

A tenth conductive layer ML10 may be disposed on the eleventh insulating layer INS11. The tenth conductive layer ML10 may be connected to the ninth conductive layer ML9, the second gate electrode GE2 of the second transistor TR2, and the second drain electrode DE2 of the second transistor TR2. For example, one side of one tenth conductive layer ML10 may be connected to the ninth conductive layer ML9 through an eighth via electrode VA8 penetrating through the eleventh insulating layer INS11 and the tenth insulating layer INS10, the other side of one tenth conductive layers ML10 may be connected to the second gate electrode GE2 through an eighth via electrode VA8 penetrating through the eleventh insulating layer INS11, and another tenth conductive layers ML10 may be connected to the second drain electrode DE2 through an eighth via electrode VA8 penetrating through the eleventh insulating layer INS11.

A twelfth insulating layer INS12 may be disposed on the tenth conductive layer ML10.

An eleventh conductive layer ML11 may be disposed on the twelfth insulating layer INS12. The eleventh conductive layer ML11 may be connected to the tenth conductive layer ML10 through a ninth via electrode VA9 penetrating through the twelfth insulating layer INS12.

A thirteenth insulating layer INS13 may be disposed on the eleventh conductive layer ML11.

A twelfth conductive layer ML12 may be disposed on the thirteenth insulating layer INS13. The twelfth conductive layer ML12 may be connected to the eleventh conductive layer ML11 through a tenth via electrode VA10 penetrating through the thirteenth insulating layer INS13.

A fourteenth insulating layer INS14 may be disposed on the twelfth conductive layer ML12.

A thirteenth conductive layer ML13 may be disposed on the fourteenth insulating layer INS14. The thirteenth conductive layer ML13 may be connected to the twelfth conductive layer ML12 through an eleventh via electrode VA11 penetrating through the fourteenth insulating layer INS14.

A fifteenth insulating layer INS15 may be disposed on the thirteenth conductive layer ML13.

The first electrode AND may be disposed on the fifteenth insulating layer INS15. The first electrode AND may be connected to the thirteenth conductive layer ML13 through a twelfth via electrode VA12 penetrating through the fifteenth insulating layer INS15.

A pixel defining layer PDL may be disposed on the first electrode AND. The pixel defining layer PDL may be disposed on an edge of the first electrode AND so as to overlap the edge of the first electrode AND. The pixel defining layer PDL may define an emission area EA of the sub-pixel. The first electrode AND may be exposed to the outside of the pixel defining layer PDL by the emission area EA of the pixel defining layer PDL.

The light emitting layer LE may be disposed on the first electrode AND and the pixel defining layer PDL.

The second electrode CAT may be disposed on the light emitting layer LE and the pixel defining layer PDL.

An encapsulation layer TFE may be disposed on the second electrode CAT. The encapsulation layer TFE may be formed as a composite film including an inorganic layer, an organic layer, and an inorganic layer. The encapsulation layer TFE may prevent moisture from permeating through into the light emitting layer LE. A color filter may be disposed on the encapsulation layer TFE.

The first source electrode SE1 of the first transistor TR1 may be connected to the second gate electrode GE2 of the second transistor TR2 through the seventh conductive layer ML7, the ninth conductive layer ML9, the tenth conductive layer ML10, the sixth via electrode VA6, the seventh via electrode VA7, and the eighth via electrode VA8. Accordingly, a scan signal (or an emission control signal) output through the first transistor TR1 may be applied to the second gate electrode GE2 of the second transistor TR2. For example, a write scan signal output through the scan transistor may be applied to the second gate electrode GE2 of the second transistor TR2. Here, the tenth conductive layer ML10 connected to the second gate electrode GE2 of the second transistor TR2 may be a scan line (e.g., a write scan line GWL).

A signal (e.g., a data voltage) output through the second transistor TR2 may be applied to the first electrode AND through the tenth to thirteenth conductive layers ML10 to ML13 and the eighth to twelfth via electrodes VA8 to VA12.

According to an aspect, the driving circuit layer DCL, the pixel circuit layer PCL, and the display element layer EMTL are disposed in the display area DAA so as to overlap each other, and thus, an area of the non-display area NDA may be reduced. In addition, the driving circuit layer DCL is disposed in the display area DAA rather than the non-display area NDA, and thus, a margin area of the non-display area NDA may be increased, and the display area DAA may be expanded to the margin area.

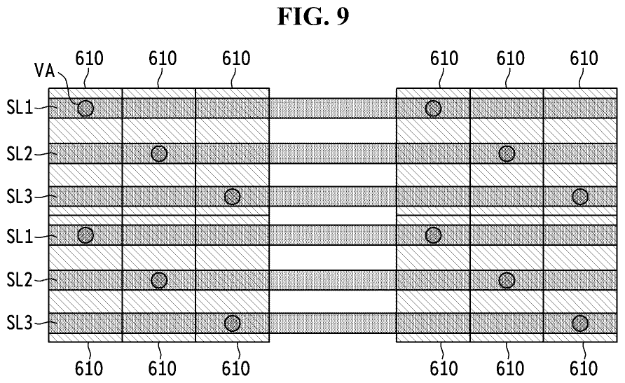

FIG. 9 is a view for describing connections between scan drivers and scan lines according to an aspect.

As illustrated in FIG. 9, the scan drivers 610 may be disposed in the display area DAA, and a plurality of scan lines SL1, SL2, and SL3 may be disposed on the scan drivers 610. Here, a first scan line SL1 may be the write scan line GWL described above, a second scan line SL2 may be the control scan line GCL described above, and a third scan line SL3 may be the bias scan line GBL described above.

The plurality of scan lines SL1, SL2, and SL3 may be connected to a plurality of scan drivers 610 through via electrodes VA penetrating through insulating layers.

A plurality of emission drivers 620 and a plurality of emission control lines EL1 and EL2 may be connected to each other through the via electrodes.

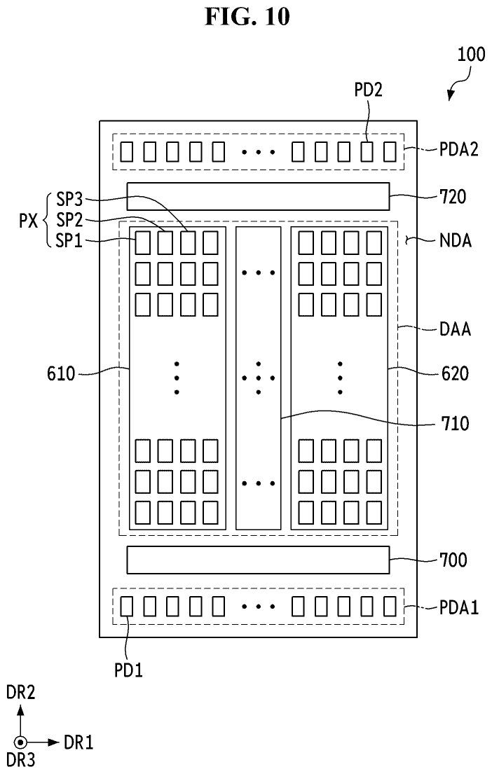

FIG. 10 is a layout diagram illustrating an example of a display panel 100 according to still another aspect.

The display panel 100 of FIG. 10 is different from the display panel 100 described above with reference to FIG. 7 in a location of the first distribution circuit 710, and such a difference will be mainly described below.

As illustrated in FIG. 10, the plurality of pixels PX (or the plurality of sub-pixels SP1, SP2, and SP3), the scan driver 610, the emission driver 620, and the first distribution circuit 710 may be disposed in the display area DAA. For example, the first distribution transistors of the first distribution circuit 710 may be disposed in the display area DAA. In this case, the first distribution circuit 710 may be disposed between the scan driver 610 and the emission driver 620 in the display area DAA. In such a case, the driving circuit layer DCL may further include the first distribution transistors of the first distribution circuit 710. In this case, in an aspect as illustrated in FIG. 6, the first distribution transistor may be a MOSFET, and in an aspect as illustrated in FIG. 8, the first distribution transistor may be an oxide-based transistor.

The first distribution circuit 710 described above may be disposed in the display area DAA of FIG. 3. For example, the first distribution circuit 710 of FIG. 3 may be disposed in the display area DAA rather than the non-display area NDA. In this case, the first distribution circuit 710 disposed in the display area DAA of FIG. 3 may be disposed between the scan driver 610 and the emission driver 620.

When the first distribution circuit 710 is further disposed in the display area DAA as described above, an area of the non-display area NDA may be further reduced.

The display device 10 according to an aspect may be applied to various electronic devices. An electronic device according to an aspect includes the display device 10 described above, and may further include modules or devices having other additional functions in addition to the display device 10.

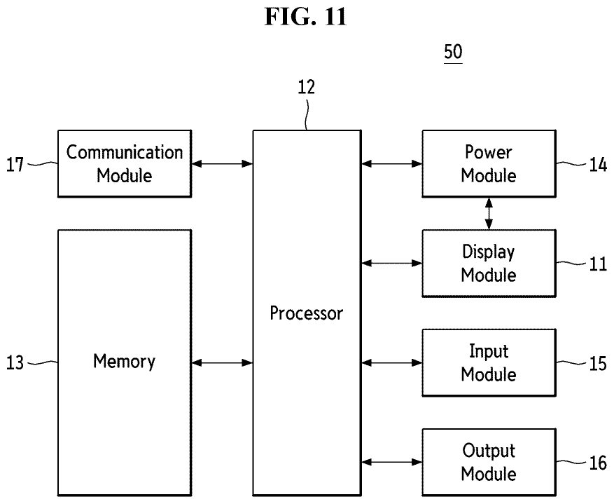

FIG. 11 is a block diagram of an electronic device according to an aspect. Referring to FIG. 11, an electronic device 50 according to an aspect may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to a user through the display module 11. The power module 14 may include a power supply module such as a power adapter or a battery device and a power conversion module converting power supplied by the power supply module to generate power necessary for an operation of the electronic device 50. The input module 15 may provide input information to the processor 12 and/or the display module 11. The non-image output module 16 may serve to receive information other than an image received from the processor 12, such as sound information, haptic information, and light emitting information, and provide the received information to the user. The communication module 17 is a module in charge of transmitting and receiving information between the electronic device 50 and an external device, and may include a receiving unit and a transmitting unit.

At least one of the respective components of the above-described electronic device 50 may be included in the display device according to the above-described aspects. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 50 rather than the display device.

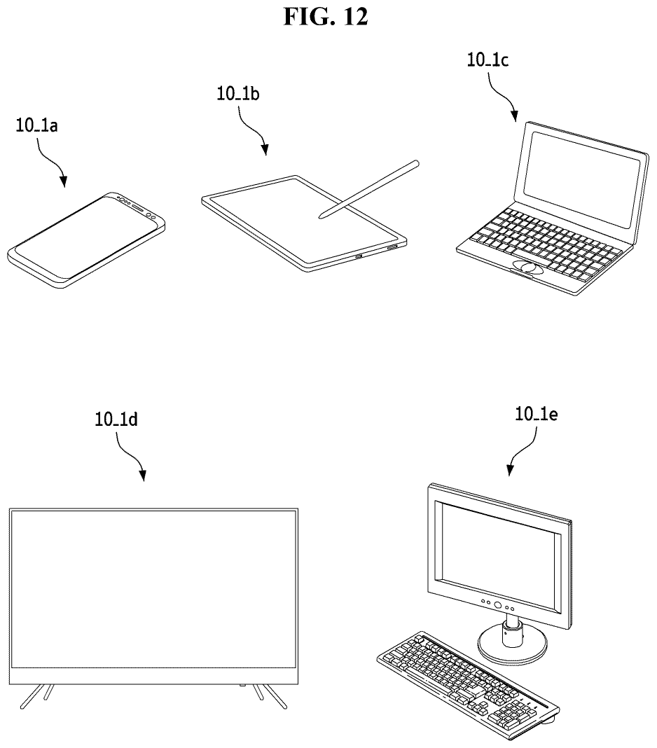

FIGS. 12 to 14 are schematic views of electronic devices according to various aspects. FIGS. 12 to 14 illustrate examples of various electronic devices to which a display device 10 according to aspects is applied.

FIG. 12 illustrates a smartphone 10_1a, a tablet personal computer (PC) 10_1b, a laptop computer 10_1c, a television (TV) 10_1d, and a monitor 10_1e for a desktop computer as examples of the electronic devices.

The smartphone 10_1a may include an input module such as a touch sensor and a communication module in addition to the display module 11. The smartphone 10_1a may process information received through the communication module or other input modules and display the processed information through the display module of the display device.

Each of the tablet PC 10_1b, the laptop computer 10_1c, the TV 10_1d, and the monitor 10_1e for a desktop computer may include a display module and an input module, similar to the smartphone 10_1a, and may further include a communication module in some cases.

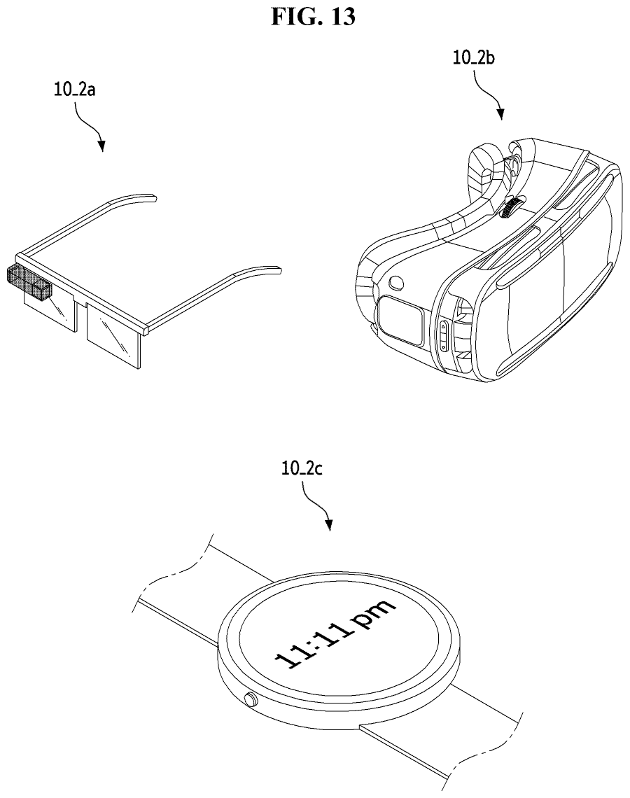

FIG. 13 illustrates a case where an electronic device including a display module is applied to a wearable electronic device. The wearable electronic device may be a smart glasses 10_2a, a head mounted display 10_2b, a smart watch 10_2c, or the like.

The smart glasses 10_2a and the head mounted display 10_2b may include a display module emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display module.

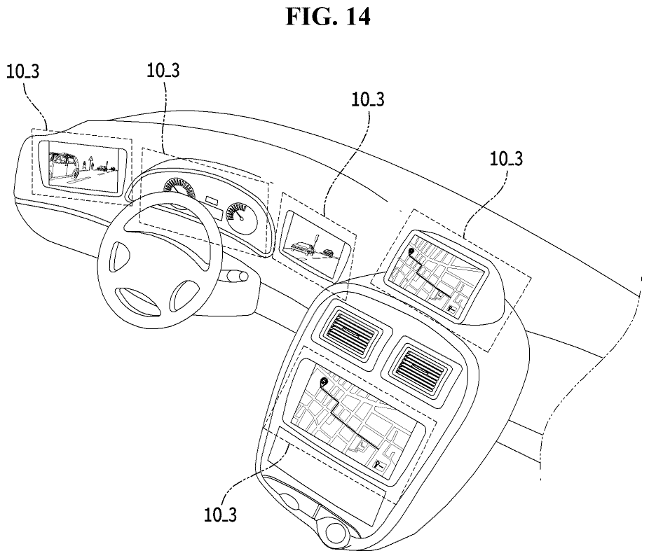

FIG. 14 illustrates a case where an electronic device including a display module is applied to a vehicle. For example, an electronic device 10_3 may be applied to an instrument board, a center fascia, or the like, of the vehicle or applied to a center information display (CID) disposed on a dashboard of the vehicle, a room mirror display substituting for a side-view mirror, or the like.

In concluding the detailed description, those skilled in the art will appreciate that many variations and modifications can be made to the preferred aspects without substantially departing from the principles of the present disclosure. Therefore, the disclosed preferred aspects of the disclosure are used in a generic and descriptive sense only and not for purposes of limitation.

What is claimed is:

1. A display device comprising:
a substrate having an upper surface, a display area and a non-display area; and
a driving circuit layer, a pixel circuit layer, and a display element layer that are disposed on the substrate,
wherein the driving circuit layer is connected to a pixel circuit of the pixel circuit layer,
the pixel circuit of the pixel circuit layer is connected to a light emitting element of the display element layer,
the driving circuit layer, the pixel circuit layer, and the display element layer are disposed on the display area of the substrate so as to overlap each other in a direction perpendicular to the upper surface of the substrate,
the driving circuit layer includes a first transistor,
the pixel circuit layer includes a second transistor provided in the pixel circuit and connected to the first transistor,
the first transistor is a metal oxide semiconductor field effect transistor (MOSFET), and
the second transistor is an oxide semiconductor transistor.

2. The display device of claim 1, wherein a source region of the first transistor is connected to a gate electrode of the second transistor.

3. The display device of claim 1, wherein the pixel circuit layer is disposed between the driving circuit layer and the display element layer.

4. The display device of claim 1, wherein the oxide semiconductor transistor includes indium gallium zinc oxide or indium gallium zinc tin oxide.

5. The display device of claim 1, wherein the driving circuit layer includes a scan driver and an emission driver.

6. The display device of claim 5, wherein an overlapping area of the display area that overlaps the scan driver and the emission driver has a smaller area than a non-overlapping area of the display area that does not overlap the scan driver and the emission driver.

7. The display device of claim 5, wherein each of the scan driver and the emission driver includes the first transistor.

8. The display device of claim 5, further comprising a distribution circuit disposed in the display area.

9. The display device of claim 8, wherein the distribution circuit is disposed between the scan driver and the emission driver in the display area.

10. A display device comprising:
a substrate having an upper surface, a display area and a non-display area; and
a driving circuit layer, a pixel circuit layer, and a display element layer that are disposed on the substrate,
wherein the driving circuit layer is connected to a pixel circuit of the pixel circuit layer,
the pixel circuit of the pixel circuit layer is connected to a light emitting element of the display element layer,
the driving circuit layer, the pixel circuit layer, and the display element layer are disposed on the display area of the substrate so as to overlap each other in a direction perpendicular to the upper surface of the substrate,
the driving circuit layer includes a first transistor,
the pixel circuit layer includes a second transistor provided in the pixel circuit and connected to the first transistor, and
each of the first transistor and the second transistor is an oxide semiconductor transistor.

11. The display device of claim 10, wherein a source electrode of the first transistor is connected to a gate electrode of the second transistor.

12. The display device of claim 10, wherein the pixel circuit layer is disposed between the driving circuit layer and the display element layer.

13. The display device of claim 10, wherein the oxide semiconductor transistor includes indium gallium zinc oxide or indium gallium zinc tin oxide.

14. The display device of claim 10, wherein the driving circuit layer includes a scan driver and an emission driver.

15. The display device of claim 14, wherein an overlapping area of the display area that overlaps the scan driver and the emission driver has a greater area than a non-overlapping area of the display area that does not overlap the scan driver and the emission driver.

16. The display device of claim 14, wherein each of the scan driver and the emission driver includes the first transistor.

17. The display device of claim 14, further comprising a distribution circuit disposed in the display area.

18. The display device of claim 17, wherein the distribution circuit is disposed between the scan driver and the emission driver in the display area.

19. An electronic device comprising a display device providing a display screen,
wherein the display device includes:
a substrate having upper surface, a display area and a non-display area; and
a driving circuit layer, a pixel circuit layer, and a display element layer that are disposed on the substrate,
the driving circuit layer is connected to a pixel circuit of the pixel circuit layer,
the pixel circuit of the pixel circuit layer is connected to a light emitting element of the display element layer,
the driving circuit layer, the pixel circuit layer, and the display element layer are disposed on the display area of the substrate so as to overlap each other in a direction perpendicular to the upper surface of the substrate,
the driving circuit layer includes a first transistor,
the pixel circuit layer includes a second transistor provided in the pixel circuit, the second transistor connected to the first transistor,
the first transistor is a MOSFET, and
the second transistor is an oxide semiconductor transistor.

20. The electronic device of claim 19, wherein the electronic device is a smartphone, a tablet personal computer (PC), a laptop computer, a television (TV), a monitor for a desktop computer, a smart glasses, a smart watch, a head mounted display, or a vehicle.
